(19) United States
(12) Patent Application Publication
(10) Pub. No.: US 2026/0022453 A1
(43) Pub. Date: Jan. 22, 2026

(54) SELECTIVE MOLYBDENUM FILL

(71) Applicant: Lam Research Corporation, Fremont, CA (US)

(72) Inventors: Sang-Hyeob LEE, Fremont, CA (US); Ishtak KARIM, San Jose, CA (US); Kaihan Abidi ASHTIANI, Cupertino, CA (US); Seshasayee VARADARAJAN, Lake Oswego, OR (US)

(21) Appl. No.: 19/124,236

(22) PCT Filed: Oct. 25, 2023
(86) PCT No.: PCT/US2023/035873

§ 371 Date: Apr. 24, 2025

Related U.S. Application Data
(60) Provisional application No. 63/381,385, filed on Oct. 28, 2022.

(51) Int. Cl. C23C 16/04; C23C 10/08; C23C 10/60; C23C 16/14; C23C 16/56; C23C 28/00

(52) U.S. Cl. CPC C23C 16/045; C23C 10/08; C23C 10/60; C23C 16/14; C23C 16/56; C23C 28/322; C23C 28/34

(57) ABSTRACT

A molybdenum silicide layer is formed on a bottom surface in a recessed feature in a silicon or silicon-germanium substrate. The bottom surface may be a silicon or silicon-germanium. A first molybdenum lay er may be deposited on or over the molybdenum silicide layer to fill the recessed feature. In some cases, a second molybdenum layer may be formed on the molybdenum silicide layer. In some cases, the second molybdenum layer may be exposed to nitrogen radicals or nitrogen-containing radicals, forming a molybdenum nitride layer on the second molybdenum layer.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Many semiconductor fabrication processes include metal fill. Metal fill may be used for connecting adjacent metal layers, and/or as contacts between metal layers and neighboring devices. As node size is reduced, uniform metal fill with low resistance becomes a challenge.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

One aspect of disclosure relates to a method. The method includes forming a molybdenum silicide layer on a bottom surface of a recessed feature on a substrate. The bottom surface includes silicon or silicon germanium. The methods further include depositing a first molybdenum layer on or over the molybdenum silicide layer to fill the feature.

In some embodiments, the method further includes exposing the molybdenum silicide layer to a reducing agent prior to depositing the first molybdenum layer. The reducing agent may includes diborane, silane, disilane, or a mixture thereof.

In some embodiments, the method further includes, prior to depositing the first molybdenum layer, forming a second molybdenum layer on the molybdenum silicide layer, and exposing the second molybdenum layer to nitrogen radicals or nitrogen-containing radicals. A portion of the second molybdenum layer is converted to a molybdenum nitride layer when exposed to the nitrogen radicals or nitrogen-containing radicals. The second molybdenum layer has a thickness of about 1 to about 10 nm. The second molybdenum layer is exposed to nitrogen radicals or nitrogen-containing radicals at a temperature of about 200 to about 600° C. The nitrogen radicals or nitrogen-containing radials may be formed in a plasma generated from ammonia, nitrogen, or a mixture thereof.

In some embodiments, the method further includes exposing the molybdenum silicide layer to nitrogen radicals or nitrogen-containing radicals. The nitrogen radicals or nitrogen-containing radicals include ammonia, nitrogen, ammonia plasma, nitrogen plasma, or a mixture thereof. The molybdenum silicide layer is exposed to nitrogen radicals or nitrogen-containing radicals at a temperature of about 200 to about 600° C. The method further includes exposing the molybdenum silicide layer to a reducing agent comprising diborane, silane, disilane, or a mixture thereof prior to exposing the molybdenum silicide layer to nitrogen radicals or nitrogen-containing radicals.

In some embodiments, the molybdenum silicide layer is formed by reacting a molybdenum containing precursor with the bottom surface at a temperature of about 200 to about 600° C.

In some embodiments, the first molybdenum layer is formed by flowing a molybdenum halide precursor or a molybdenum oxyhalide precursor. The first molybdenum layer is formed by further flowing hydrogen. The molybdenum halide precursor includes molybdenum pentachloride. The molybdenum oxyhalide precursor includes molybdenum oxychloride.

In some embodiments, the first molybdenum layer is free of voids.

In some embodiments, the molybdenum silicide layer has a thickness of about 0.3 to about 10 nm.

In some embodiments, the molybdenum silicide layer has a thickness of about 2 to about 20 nm.

In some embodiments, the first molybdenum layer has a thickness of about 10 to about 100 nm.

Another aspect of the disclosure relates to a method. The method includes selectively forming a molybdenum silicide layer on a bottom surface including silicon or silicon-germanium in a recessed feature of a substrate, and selectively depositing a first molybdenum layer on or over the molybdenum silicide layer to fille the feature. A substrate temperature is about 200 to about 600° C.

In some embodiments, the molybdenum silicide layer is formed using a molybdenum pentachloride.

In some embodiments, the recessed feature further comprises a top surface and one or more sidewalls, wherein the top surface and the one or more sidewalls comprise silicon oxide, silicon nitride, or a mixture or combination thereof.

In some embodiments, the method further includes selectively depositing a second molybdenum layer on the molybdenum silicide layer prior to selectively depositing the first molybdenum layer, and exposing the second molybdenum layer to nitrogen radicals or nitrogen-containing radicals. The nitrogen radicals or nitrogen-containing radicals include ammonia, nitrogen, ammonia plasma, nitrogen plasma, or a mixture thereof. The second molybdenum layer may have a thickness of about 0.3 to about 10 nm. A substrate temperature is about 200 to about 600° C. The second molybdenum layer is formed using a molybdenum pentachloride or molybdenum oxy chloride.

In some embodiments, the second molybdenum layer has a thickness of about 1.0 to about 10 nm.

In some embodiments, the method further includes exposing the molybdenum silicide layer to nitrogen radicals or nitrogen-containing radicals. The nitrogen radicals or nitrogen-containing radicals include ammonia, nitrogen, ammonia plasma, nitrogen plasma, or a mixture thereof. A substrate temperature is about 200 to about 600° C.

In some embodiments, at least one of the molybdenum silicide layer and the first molybdenum layer is preferentially formed on the bottom surface with respect to sidewall surfaces in the recessed feature.

In some embodiments, the molybdenum layer or the first molybdenum layer is formed using a molybdenum pentachloride or molybdenum oxychloride.

In some embodiments, the method further includes exposing the molybdenum layer to a reducing agent. The reducing agent includes diborane, silane, disilane, or a mixture thereof.

Still another aspect of the disclosure relates to a semiconductor device. The semiconductor device includes a substrate including silicon or silicon-germanium, and a recessed feature formed on the substrate. The recessed feature includes a top surface, one or more sidewall surfaces, and a bottom surface. The bottom surface includes silicon or silicon-germanium. The semiconductor device further includes a molybdenum silicide layer on the bottom surface, and a first molybdenum fill on or over the molybdenum silicide layer in the recessed feature. The first molybdenum fill is in direct contact with the one or more sidewall surfaces.

In some embodiments, the semiconductor device further includes a second molybdenum layer on the molybdenum silicide layer. The second molybdenum layer has a thickness of about 0.3 to about 10 nm, or about 1.0 to about 10 nm. The semiconductor device further includes a molybdenum nitride layer formed on the second molybdenum layer. The first molybdenum fill is free of a void.

These and other aspects are described further below with reference to the drawings.

### BRIEF DESCRIPTION OF THE DRAWINGS

FIG. 1 shows a cross-sectional schematic illustration of a feature of an example substrate.

FIG. 2 illustrates a flow chart of an example of a selective deposition method to fill a feature of a substrate according to some embodiments.

FIGS. 3A-3C show cross-sectional schematic illustrations of a feature of an example substrate according to some embodiments.

FIGS. 4A-4D show cross-sectional schematic illustrations of a feature of an example substrate according to some embodiments.

FIGS. 5A-5E show cross-sectional schematic illustrations of a feature of an example substrate according to some embodiments.

FIGS. 6-9 are schematic diagrams of examples of process chambers for performing methods in accordance with some embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

In the present disclosure, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication. A wafer or substrate used in the semiconductor device industry typically has a diameter of 200 mm, or 300 mm, or 450 mm. The following detailed description assumes the present disclosure is implemented on a wafer. However, the present disclosure is not so limited. The work piece may be of various shapes, sizes, and materials. In addition to semiconductor wafers, other work pieces that may take advantage of the present disclosure include various articles such as printed circuit boards and the like.

Substrates may include features such as trenches or holes. The term “feature” as used herein refers to a non-planar structure of a substrate, or semiconductor substrate. Examples of features, which may also be referred to as “negative features” or “recessed features,” include trenches, holes, vias, gaps, recessed regions, and the like. These terms may be used interchangeably in the present disclosure. One example of a feature is a hole or via in a semiconductor substrate or in a layer on the substrate. Another example is a trench in a substrate or layer. A feature typically has an aspect ratio (depth to lateral dimension). A feature may be characterized by one or more of narrow and/or re-entrant openings, constrictions within the feature, and high aspect ratios. A feature having a high aspect ratio can have a depth to lateral dimension ratio equal to or greater than about 10:1, equal to or greater than about 15:1, equal to or greater than about 20:1, equal to or greater than about 25:1, equal to or greater than about 30:1, equal to or greater than about 40:1, equal to or greater than about 50:1, or equal to or greater than about 100:1. In various embodiments, the feature may have an under-layer, such as a diffusion barrier layer or adhesion layer. A diffusion barrier is a layer that prevents diffusion of species between layers. An adhesion layer is a layer that promotes adhesion of a layer to an underlying layer. Non-limiting examples of under-layers include dielectric layers and conducting layers, e.g., silicon oxides, silicon nitrides, undoped silicon carbides, oxygen-doped silicon carbides, nitrogen-doped silicon carbides, metal oxides, metal nitrides, metal carbides, and metal layers.

Features of a substrate can be of various types. In some embodiments, a feature can have straight sidewalls, positively sloped sidewalls, or negatively sloped sidewalls. In some embodiments, a feature can have sidewall topography or sidewall roughness, which may occur as a result of an etch process to form the feature. In some embodiments, a feature can have a feature opening that is greater at the top of the feature than at the bottom, or a feature can have a feature opening that is greater at the bottom of the feature than at the top.

In the present disclosure, the terms “depositing,” “forming,” and “filling” may be used interchangeably. Also, the terms “layer,” “film,” and “fill” may be used interchangeably. One of ordinary skill in the art would understand that “forming” a layer in any of many stages of integrated circuit fabrication can refer to “depositing” a thin layer by one of various thin film forming methods such as physical vapor deposition (PVD), chemical vapor deposition (CVD), low pressure chemical vapor deposition (LPCVD), plasma enhanced chemical vapor deposition (PECVD), hot-wire chemical vapor deposition (hot-wire CVD), atomic layer deposition (ALD), or plasma enhanced atomic layer deposition (PEALD) due to the decreased feature sizes in a semiconductor device. Also, one of ordinary skill in the art would understand “forming” a layer for extended time period can “fill” a feature in a substrate.

Provided herein are methods of filling features with molybdenum (Mo) that may be used for logic and memory applications. Molybdenum offers several benefits over other metals such as cobalt (Co), ruthenium (Ru), and tungsten (W): (i) barrier-less and liner-less molybdenum film deposition is more feasible on oxides and nitrides as compared to deposition of cobalt, ruthenium, and tungsten, (ii) Mo resistivity scaling is better than that of tungsten, and (iii) Mo intermixing with underlying cobalt (Co) is not expected compared to Ru intermixing with Co at temperatures less than 450° C.

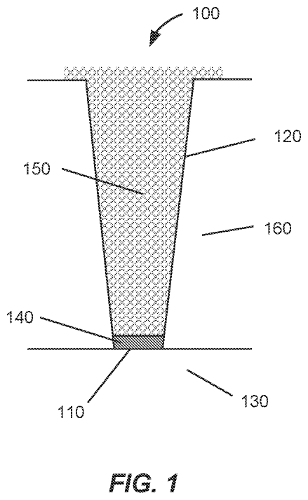

FIG. 1 depicts a cross-sectional schematic illustration of a feature 100 of an example substrate. The feature 100 includes a bottom surface 110 and one or more sidewall surfaces 120. The feature 100 may be a trench or via, for example. The bottom surface 110 may be a silicon (Si) or silicon-germanium (SiGe) in or on a substrate 130. The substrate may include a partially fabricated integrated circuit. In some embodiments, the bottom surface 110 may be an active junction including an n+ region or a p+ region formed in the substrate 130. The feature 100 may include a metal silicide 140 formed on the bottom surface 110 as a metal interconnect. For example, molybdenum silicide (MoSi) may be used as the metal silicide 140. As used herein, “MoSi” refers to any molybdenum silicide having any appropriate relative amounts of molybdenum and silicon. In some embodiments, a chemical formula for MoSi can be represented as MoSiₓ where 1≤x≤2. MoSiₓ can be MoSi₂, for example.

The feature 100 may include a metal fill layer 150. In some embodiments, molybdenum (Mo) fill may provide an electrical interconnect to the underlying metal silicide 140 and Si or SiGe substrate 130. The feature 100 may be formed in a patterned dielectric layer 160 that may keep the metal interconnects insulated from each other. The patterned dielectric layer 160 may include tetraethyl orthosilicate (TEOS), fluorosilicate glass (FSG), spin-on glasses, flowable oxides, carbon doped oxides, etc.

In some embodiments, the one or more sidewall surfaces 120 may be part of the patterned dielectric layer 160 surrounding the feature 100. In some embodiments, the sidewall surfaces 120 may be oxides (e.g., silicon oxide), nitrides (e.g., silicon nitride), or a mixture thereof. The nitrides may be silicon-based nitrides or silicon-based oxynitrides.

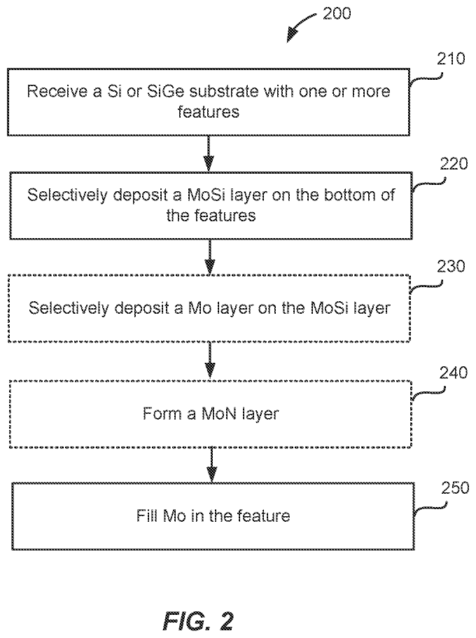

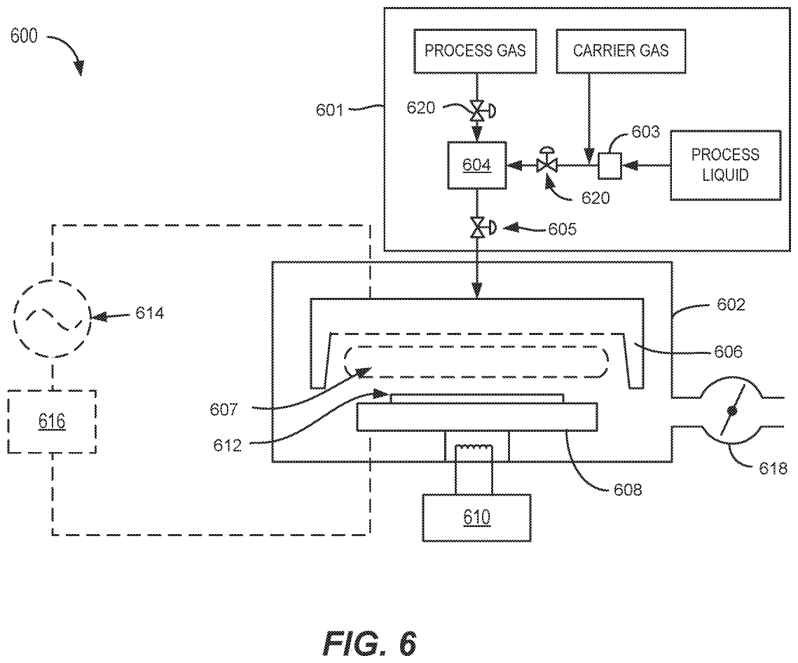

The methods described herein include filling a feature with metal to form a filled feature as shown in FIG. 1. FIG. 2 illustrates a flow chart of an example of a selective deposition method to fill a feature of a substrate according to some embodiments. The operations of a process 200 may be performed in different orders and/or with different, fewer, or additional operations. One or more operations of the process 200 may be performed using a substrate processing apparatus shown in FIGS. 6-9. In some embodiments, the operations of the process 200 may be implemented, at least in part, according to software stored in one or more non-transitory computer readable media.

In operation 210, a Si or SiGe substrate with one or more features may be received in a process chamber. The one or more features may include a trench, hole, via, or other feature having a volume defined by a bottom surface and sidewall surfaces. The bottom surface may include n+ region and/or p+ region formed in the Si or SiGe substrate in a logic device. After operation 210, a pre-treatment may be optionally performed to reduce any undesirable metal-oxide formed on the surfaces in the features. Pre-treatment may include exposing the feature to a hydrogen-containing plasma. For example, the hydrogen-containing plasma may be generated from hydrogen gas (H₂).

In operation 220, molybdenum silicide (MoSi) layer may be formed in the feature using a molybdenum (Mo) containing precursor. In some embodiments, a Mo-containing precursor may be provided to the Si or SiGe substrate at elevated temperature. The MoSi layer may be formed from the reaction between Mo-containing precursor and underlying Si or SiGe. The thickness of MoSi layer may range about 0.3 to about 10 nm, or about 2 to about 20 nm, or about 3 to about 7 nm, or about 5 nm.

The Mo layer may be deposited using a molybdenum-containing precursor in a vapor deposition process. Molybdenum-containing precursors include molybdenum halide precursors and molybdenum oxyhalide precursors. Examples of molybdenum halide precursors include molybdenum chloride. Molybdenum chloride is given by the formula MoClₓ, where x is 2, 3, 4, 5, or 6, and includes molybdenum dichloride (MoCl₂), molybdenum trichloride (MoCl₃), molybdenum tetrachloride (MoCl₄), molybdenum pentachloride (MoCl₅), and molybdenum hexachloride (MoCl₆). In some embodiments. MoCl₅ or MoCl₆ are used. While the description chiefly refers to MoClₓ precursors, in other embodiments, other molybdenum halide precursors may be used. Molybdenum halide precursors are given by the formula MoX_{z}, where X is a halogen (fluorine (F), chlorine (Cl), bromine (Br), or iodine (I)) and z is 2, 3, 4, 5, or 6. Examples of MoX_{z} precursors include molybdenum fluoride (MoF₆). In some embodiments, a non-fluorine-containing MoX_{z} precursor is used to prevent fluorine etch or incorporation. In some embodiments, a non-bromine-containing and/or a non-iodine-containing MoX_{z} precursor is used to prevent etch or bromine or iodine incorporation.

Examples of molybdenum oxyhalide precursor include molybdenum tetrafluoride oxide (MoOF₄), molybdenum tetrachloride oxide (MoOCl₄), molybdenum dichloride dioxide (MoO₂Cl₂), molybdenum dibromide dioxide (MoO₂Br₂), and molybdenum oxyiodides (MoO₂I and Mo₄O₁₁I). Further examples of molybdenum oxyhalides include MoO₂F₂, MoO₂I₂, MoOBr₄, and MoOI₄.

The Mo layer may be formed in the feature by atomic layer deposition (ALD) or chemical vapor deposition (CVD). In some embodiments, thermal ALD or thermal CVD may be used. In a thermal process, a plasma is not used. ALD is a surface-mediated deposition technique in which doses of reactants are sequentially introduced into a deposition chamber. For example, one or more cycles of sequential doses of a Mo-containing precursor and a reactant may be used to deposit Mo. For example, in the deposition of a MoSi layer, molybdenum halide precursor may be used as a precursor and H₂ as a reducing agent. Doses of the molybdenum halide precursor and H₂ are sequentially introduced into the process chamber with a purge gas, such as argon, flowed between the molybdenum halide dose and the H₂ dose. For ALD, the temperature of the substrate and the pressure of the chamber may be controlled. For example, to form a MoSi layer, the substrate may be heated to about 200 to about 600° C., or about 300 to about 500° C. In some embodiments, the process chamber may be pressurized to about 5 to about 100 Torr, or about 20 to about 50 Torr, or about 30 to about 70 Torr. In some embodiments, the temperature and/or pressure may be used to control the rate of reactions.

In some embodiments, Mo layer deposition (and/or subsequent Mo fill) may involve CVD. In a CVD process, the molybdenum-containing precursor and a reactant are in vapor phase together in the process chamber. Generally speaking, a CVD process deposits in a feature (or fills a feature) faster than an ALD process. In one example, the precursor may be a molybdenum halide, such as MoClₓ as disclosed herein, or a molybdenum oxychloride, such as MoO₂Cl₂, or MoOCl₄, and is flowed into the process chamber with a reactant, such as H₂. In this example, the wafer is simultaneously exposed to the precursor and a reactant, which react and deposits Mo in the feature. During Mo layer deposition, in addition to Mo-containing precursor, H₂ may also be introduced in the process chamber as a reducing agent.

In operation 220, in some embodiments, a Mo-containing precursor may react with an underlying Si or SiGe substrate at elevated temperature to form the MoSi layer. In this context, selective deposition refers to deposition that is easier on a semiconductor, metal, or metal alloy surface than on oxide or nitride surfaces. For selective Mo deposition, a Mo-containing precursor may be nucleated and grown more easily on the bottom of the feature, which is Si or SiGe substrate, with respect to the sidewall surfaces including silicon oxide, silicon nitride, or a mixture thereof. For example, Mo may be predominantly or substantially predominantly nucleated and grown on the Si or SiGe without substantially nucleating and growing on the sidewall surfaces made of silicon oxide, silicon nitride, or a mixture thereof.

Process conditions such as the identity of the Mo-containing precursor, the reducing agent, the process temperature, the process pressure, and the exposure time may affect the selectivity of the Mo film being deposited. Different Mo-containing precursors have different process windows in which molybdenum film may be selectively deposited. In some embodiments, molybdenum halide precursor may be used as a Mo-containing precursor. During the deposition, substrate temperature may be about 200 to about 600° C., or about 300 to about 500° C. The process chamber pressure may be about 5 to about 100 Torr, or about 20 to about 50 Torr, or about 30 to about 70 Torr. Molybdenum pentachloride (MoCl₅) has a large process window, i.e., a large temperature and pressure range, where the precursor retains its selectivity. For example, MoCl₅ may be selectively deposited on a semiconductor, metal, or metal alloy material with respect to a dielectric including silicon oxide, silicon nitride, or a mixture thereof where the substrate temperature is about 200 to about 600° C., or about 300 to about 500° C. Generally speaking, higher process temperatures and higher process pressures may reduce the selectivity of the deposited gas. For example, at higher temperatures, a precursor gas such as MoCl₅ may lose its selectivity and deposit molybdenum film on both a metal or metal alloy surface and a dielectric surface within a feature.

MoCl₅ may be reacted with different reactants to deposit a molybdenum film. Described below are examples of deposition of molybdenum film within a feature using a MoCl₅ precursor and different process controls. In an example, the MoCl₅ precursor may react with a hydrogen (H₂) reactant using the deposition methods described above. In the description herein, Mo-containing precursors may react with hydrogen (H₂) as the reactant (also referred to as a hydrogen reactant or H₂ reactant). However, other reactants may be used instead of hydrogen including other hydrogen-containing reactants such as diborane (B₂H₆), silane (SiH₄), disilane (Si₂H₆), and ammonia (NH₃), as appropriate. While reactants such as B₂H₆ and/or SiH₄ are stronger reducing agents, they can also result in higher resistivity. Thus, in some embodiments, using H₂ as described herein may be advantageous. Process temperatures for selective deposition of the molybdenum film may be about 200 to about 600° C., or about 300 to about 500° C. At these temperatures, the molybdenum film is selectively deposited on semiconductor, conductive metal, or metal compound (e.g., metal alloy) surfaces, such as a Si, SiGe, MoSi, or molybdenum nitride (MoN) surface, in a feature relative to dielectric surfaces. The molybdenum film grows from the locations where the semiconducting or conductive surfaces are located in a feature. If the surface is a Si or SiGe substrate at the bottom of the feature, the molybdenum film may be deposited and grown from Si or SiGe at the bottom of the feature. In another example, the molybdenum film may be deposited using the MoCl₅ precursor and the H₂ reactant, but at higher temperatures, i.e., above 800° C., the MoCl₅ may lose its selectivity, and may deposit the molybdenum film deposited on both the dielectric and conductive surfaces within the feature.

In some embodiments, low reactant partial pressure increases the selectivity due to the increase in nucleation delay on dielectrics. For example, the reactant partial pressure may be, for example, about 0.05 to about 5 Torr, or about 0.3 to about 3 Torr.

In some embodiments, operation 220 may involve exposure to the molybdenum halide precursor with a reactant gas to deposit Mo. The reactant gas may be hydrogen (H₂) although other reducing agents such as silane (SiH₄), diborane (B₂H₆), germane (GeH₄), ammonia (NH₃), and hydrazine (N₂H₄) may also be used. For example, a cycle for sequentially pulsing in the order of molybdenum halide precursor, argon (Ar), hydrogen (H₂), and argon (Ar) may be repeated for a predetermined number (N) of cycles. In another example, molybdenum halide precursor may be pulsed with hydrogen (H₂) for a predetermined number (N) of cycles. In yet another example, a mixture of molybdenum halide precursor and hydrogen (H₂) may be simultaneously dosed for a predetermined dose period.

In some embodiments, before onset of subsequent operations, the MoSi layer formed in operation 220 may be treated by one or more reducing agents (e.g., hydrogen-containing reactants) for controlling the nucleation of Mo on the MoSi layer. For treatment, the MoSi layer may be exposed to hydrogen-containing reactants such as B₂H₆, SiH₄, Si₂H₆, or NH₃, at a temperature of about 200 to about 600° C., or about 300 to about 500° C. The treatment may increase the nuclei density of Mo on the MoSi layer, which aids and facilitates the nucleation and growth of Mo that may be subsequently formed on the MoSi layer. For example, treating the surface of the MoSi layer using the hydrogen-containing reactants may promote the uniform and continuous growth of Mo layer on the MoSi layer. In another example, the treatment may modify the MoSi layer (e.g., the surface of MoSi layer) such that Mo is more reactive to foreign reactants than Si in MoSi. For example, the MoSi layer may be exposed to nitrogen radicals or nitrogen-containing radicals for nitridization after MoSi is treated by hydrogen-containing reactants. Nitrogen radicals or nitrogen-containing radials may include ammonia, nitrogen, ammonia plasma, nitrogen plasma, or a mixture thereof. In one example, nitrogen radicals or nitrogen-containing radicals may be formed in a plasma generated from ammonia or nitrogen. After nitridization, the relative amount of MoN may be greater than SiN.

In optional operation 230, a molybdenum (Mo) metal layer may be selectively deposited on the MoSi layer. A Mo layer with a thickness of about 0.3 to about 10 nm, or about 1 to about 10 nm, or about 3 to about 7 nm, or about 5 nm may be formed by ALD or CVD. In some embodiments, the Mo layer may be deposited selectively or substantially selectively on the MoSi layer with a bottom-up growth, without deposition or with significantly less deposition on the sidewall surfaces including oxide, nitride, or a mixture thereof. The bottom-up growth may be advantageous in obtaining a continuous, Mo layer. In some embodiments, in the subsequent operations, a portion of Mo layer formed may react with Si in MoSi layer or underlying Si or SiGe substrate to prevent diffusion of silicon into another adjacent layer.

The Mo-containing precursors for optional operation 230 may include molybdenum halide precursor or molybdenum oxyhalide precursor as described above.

The substrate temperature during Mo layer deposition may be about 200 to about 600° C., or about 300 to about 500° C. The process chamber may be pressurized about 5 to about 100 Torr, or about 20 to about 50 Torr, or about 30 to about 70 Torr. During Mo layer deposition, in addition to Mo-containing precursor, H₂ may also be introduced in the process chamber as a reducing agent. In some embodiments, the Mo-containing precursor for optional operation 230 may be selected to be the same as the one for operation 220.

In optional operation 240, a molybdenum nitride (MoN) layer may be formed as a diffusion barrier to prevent silicon diffusion from MoSi formed on the bottom of the feature. In some embodiments, a MoN layer may be formed by nitridizing a portion of Mo layer formed in optional operation 230. The Mo layer may be exposed to nitrogen radicals or nitrogen-containing radicals to modify a portion of the Mo to MoN. During nitridization, ammonia, nitrogen, ammonia plasma, nitrogen plasma or a mixture thereof may be provided to the surface of Mo layer such that a portion of Mo layer is converted to MoN. The substrate temperature during nitridization may be about 200 to about 600° C., or about 300 to about 500° C. The process chamber pressure may be about 1 to about 10 Torr, or about 4 to about 6 Torr. After nitridization, an upper portion of Mo layer may be converted to MoN, and a lower portion of Mo layer may remain intact. In another example, an upper portion of Mo layer may be converted to MoN from nitridization, and a lower portion of Mo layer may be silicidized to MoSi from the reaction with Si diffused from MoSi or Si substrate. MoN as used herein refers to any appropriate ratio of nitrogen to molybdenum.

In some embodiments, a MoN layer may be directly formed on the MoSi layer without forming a Mo layer between the MoN layer and the MoSi layer. The MoSi layer may be exposed to nitrogen radicals or nitrogen-containing radicals for nitridizing the MoSi layer. For example, ammonia, nitrogen, ammonia plasma, nitrogen plasma, or a mixture thereof may be provided to the MoSi layer for nitridization. After nitridization, MoN may be formed on the surface of MoSi layer. The substrate temperature during nitridization may be about 200 to about 600° C., or about 300 to about 500° C. In some embodiments, during nitridization, a mixture of MoN, SiN, and/or MoSiN may be formed from MoSi. The amount of MoN formed may depend on various nitridization parameters, including a ratio of Mo/Si in the MoSi layer, nitridization thermodynamics in a nitrogen-containing atmosphere, and plasma conditions in the reaction chamber. SiN is electrically insulating and may not be suitable as filling composition. The nitridization temperature and/or time period may be controlled to reduce Si diffusion from underlying Si or SiGe substrate toward MoSi. Reducing the relative amount of Si may also reduce the amount of SiN, and may increase the relative amount of MoN.

In some embodiments, prior to nitridization, a MoSi layer may be treated by one or more reducing agents (e.g., hydrogen-containing reactants) to increase Mo nuclei density in MoSi as disclosed herein. The treatment may make Mo more reactive to nitrogen radicals or nitrogen-containing radicals relative to Si during the nitridization. For example, the amount of MoN may be greater than the amount of SiN for MoSi layer after exposed cy one or more reducing agents. Prevalence of MoN over SiN after nitridization in MoSi may maintain the electrical resistance of selective Mo fill low enough to work as an electrically conductive interconnect.

In operation 250, Mo is deposited to fill the feature. In some embodiments, the thickness of Mo fill may be about 10 to about 100 nm. In some embodiments, Mo fill may extend above the top (or top surface) of the dielectric (or top surface of the feature, or other layer in which the feature is formed). In some embodiments, the Mo-containing precursor may selectively or substantially selectively nucleate and grow on the MoN layer optionally formed in operation 240. The Mo-containing precursor may not or substantially may not be nucleated from the sidewall surfaces including oxide, nitride, or a mixture thereof. The deposition conditions for the Mo fill in operation 250 may be similar to those in operation 220 and/or operation 230. For example, the Mo-containing precursor in operation 250 may be the same as the precursor used in operation 220 and/or operation 230. For example, the Mo-containing precursor may include molybdenum halide (e.g., MoCl₅ or MoCl₆) or molybdenum oxyhalide. The substrate temperature during Mo fill may be about 200 to about 600° C., or about 300 to about 500° C. The process chamber may be pressurized about 5 to about 100 Torr, or about 20 to about 50 Torr, or about 30 to about 70 Torr. During Mo layer deposition, in addition to Mo-containing precursor, H₂ may also be introduced in the process chamber as a reducing agent. The Mo fill may be performed by any suitable method, and may include ALD, PEALD, CVD, or PECVD. Deposition may remain selective, with bottom-up fill used to form Mo layer in the feature. Alternately, deposition may transition from selective deposition to a more conformal deposition where Mo nucleates on the oxide or nitride sidewall surfaces as well as MoN layer. For example, initial Mo may be filled by ALD, then upper volume in the feature may be filled by CVD.

In another embodiment, in operation 250, Mo may be selectively filled from the MoSi layer formed in operation 220, without forming a Mo layer (operation 230) and a MoN layer (operation 240)). In this single stage Mo deposition. Mo may fill the feature volume without performing any intermediate stage operations, e.g., forming selective Mo layer in operation 230 and/or without performing nitridization of Mo metal layer in operation 240. In the single stage deposition of Mo directly on the MoSi, Mo deposition may remain selective, with bottom-up fill used to fill the volume in the feature, or may transition from selective deposition to a more conformal deposition as some Mo begins to nucleate on the sidewall surfaces, reducing the selectivity. The Mo fill conditions may be configured to prevent or minimize silicon diffusion into the Mo fill. For example, the substrate temperature (i.e., fill temperature) may be about 200 to about 600° C., or about 300 to about 500° C. The Mo fill may be performed by any suitable method, and may include ALD, PEALD, CVD, or PECVD.

After operation 250, Mo fill may not be uniform for each feature filled. For example, some Mo fills with several facets may extend above the top (or top surface) of the dielectric (or top surface of the feature, or other structure in which Mo is filled), while other Mo fills may not completely fill the feature. Mo fill process conditions may be configured such that all Mo overfills above the top of the dielectric. Subsequently, an optional process of chemical mechanical planarization (CMP) may be adapted to remove any excess Mo that extends above the top of the dielectric.

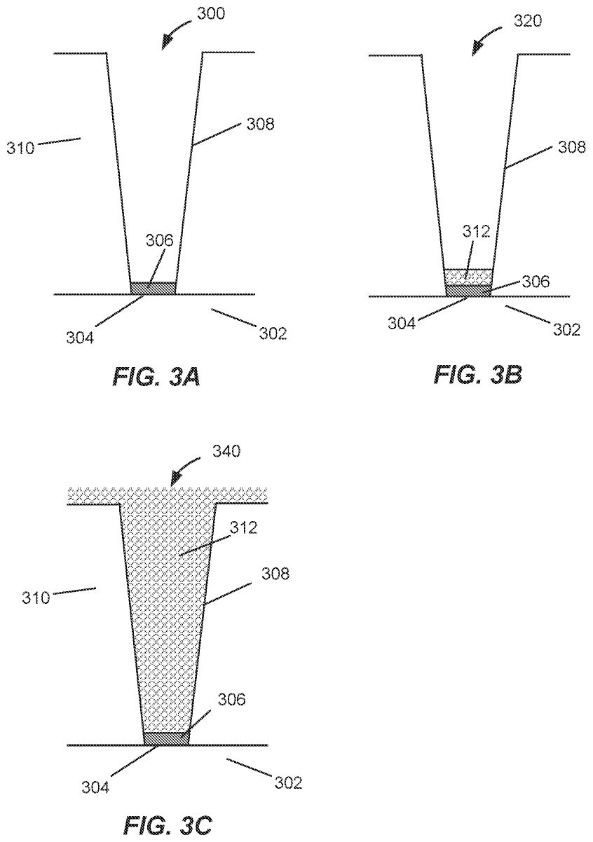

FIGS. 3A-3C show cross-sectional schematic illustrations of a feature of an example substrate after certain operations according to some embodiments. FIGS. 3A-3C show embodiments including operations 220 and 250 in FIG. 2. FIG. 3A is an embodiment after operation 220 is performed for a patterned feature 300 on a Si or SiGe substrate 302. For example, the depth of the patterned feature 300 may be about 10 to about 100 nm. The width of the feature may be equal to or greater than 5 nm, or about 10 nm. The Si or SiGe substrate 302 may include n+ and/or p+ region formed at the bottom surface 304 of the patterned feature 300. A MoSi layer 306 may be selectively formed on the bottom surface 304 relative to the sidewall surfaces 308 of the dielectric 310 including oxide, nitride, or a mixture thereof. For example, a Mo layer may be selectively deposited by ALD or CVD on the Si or SiGe substrate 302 by flowing MoClₓ as Mo-containing precursor. A MoSi layer 306 may be formed by reacting a Mo-containing precursor with underlying Si or SiGe at elevated temperature, e.g., about 200 to about 600° C., or about 300 to about 500° C. The MoSi layer thickness may be about 0.3 to about 10 nm, or about 2 to about 20 nm, or about 3 to about 7 nm, or about 5 nm. In some embodiments, after the MoSi layer 406 is formed, the MoSi layer 406 may be optionally post-treated using one or more reducing agents (e.g., hydrogen-containing agents such as B₂H₆, SiH₄, Si₂H₆, or NH₃) to facilitate forming Mo nuclei in the MoSi layer, thereby promoting Mo layer formation (or fill) in the subsequent process.

FIG. 3B is an embodiment of patterned feature 300 while operation 250 is performed. In this embodiment, a Mo layer 312 may be selectively formed on the MoSi layer 306, relative to the sidewall surfaces 308. The process conditions for the Mo layer 312 deposition may be identical or substantially identical to those for the Mo layer in forming the MoSi layer 306 shown in FIG. 3A.

FIG. 3C is an embodiment of feature 320 after operation 250 is completed. In this embodiment, the Mo layer 312 may be allowed to selectively grow with bottom-up, and void-free fill in the feature 340. This selective Mo fill may not necessitate forming one or more lining layer or barrier layer on the sidewall surfaces 308 in the feature 340, leading to maximum Mo fill volume. Also, void free, bottom-up Mo growth in the feature 340 may result in dense, high quality fill structure. The metal fill resistance is inversely proportional to the metal fill volume. Filling the feature solely with metal without any barrier or liner, or any void in the feature may maximize the metal fill volume, resulting in the reduced electrical resistance (i.e., increased electrical conductivity). In some embodiments, Mo fill may be formed over the surface of the dielectric 310. CMP may be adapted to remove the excess Mo above the top of the dielectric 310. While FIG. 3B and FIG. 3C are described as separate operations, operations shown in FIG. 3B and FIG. 3C may belong to the same operation, and may be combined into the same operation. In some embodiments, FIG. 3B may represent an initial stage and FIG. 3C may represent a later stage of bottom up fill.

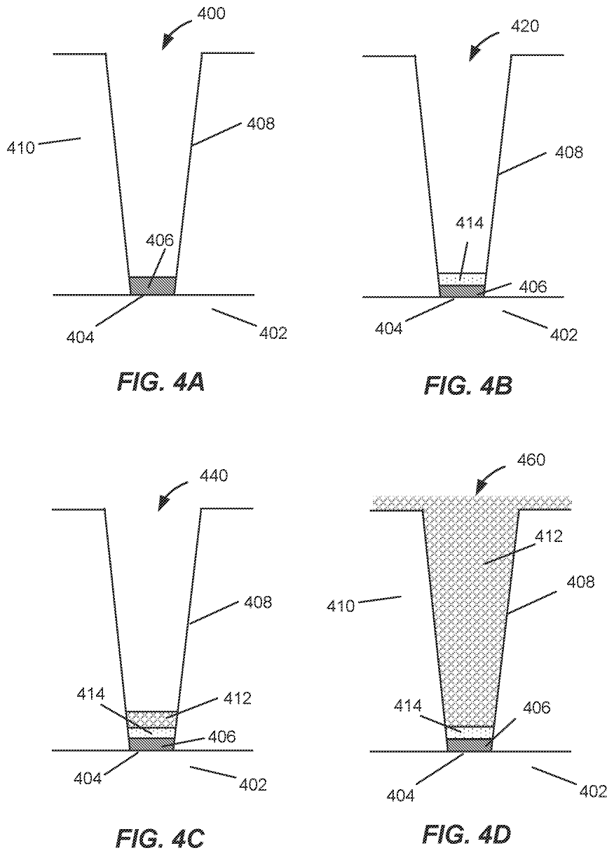

FIGS. 4A-4D show cross-sectional schematic illustrations of a feature of an example substrate after and/or during certain operations according to some embodiments. FIGS. 4A-4D show embodiments including operations 220, 240, and 250 in FIG. 2. FIGS. 4A-4D may not include operation 230 of forming a Mo layer.

FIG. 4A is an embodiment after operation 220 is performed for a patterned feature 400 on a Si or SiGe substrate 402. For example, the Si or SiGe substrate 402 may include n+ and/or p+ region formed at the bottom surface 404 of the patterned feature 400. A MoSi layer 406 may be selectively formed on the Si or SiGe bottom surface 404 relative to the sidewall surfaces 408. The process for forming MoSi layer may be the identical or substantially identical to the MoSi layer in FIG. 3A. For example, a Mo layer may be deposited on the n+ and/or p+ regions in the silicon substrate by ALD or CVD at the deposition temperature of about 200 to about 600° C., or about 300 to about 500° C. The MoSi layer 406 thickness may be about 0.3 to about 10 nm, or about 2 to about 20 nm, or about 3 to about 7 nm, or about 5 nm. In some embodiments, after the MoSi layer 406 is formed, the MoSi layer 406 may be optionally post-treated using one or more reducing agents (e.g., hydrogen-containing agents such as B₂H₆, SiH₄, Si₂H₆, or NH₃) to facilitate forming Mo nuclei in the MoSi layer, thereby promoting MoN formation over SiN in the subsequent process.

FIG. 4B is an embodiment of patterned feature 400 after operations 220 and 240 are sequentially complete. A MoN layer 414 may be formed by nitridizing a portion of the MoSi layer 406. The MoN layer 414 may function as a diffusion barrier. The MoSi layer 406 may be exposed to nitrogen radicals or nitrogen-containing radicals for nitridization. Nitrogen radicals or nitrogen-containing radicals may include ammonia, nitrogen, ammonia plasma, nitrogen plasma, or a mixture thereof. Nitridization may be performed about 200 to about 600° C., or about 300 to about 500° C. During nitridization, the MoSi layer 406 may be converted to a mixture including MoSiN, MoN, and/or SiN.

FIG. 4C is an embodiment of feature 420 while operation 250 is being performed, which is substantially identical to the feature 320 shown in FIG. 3B. While operation 250 is being performed, in addition to Mo-containing precursor, H₂ may also be introduced in the process chamber as a reducing agent. The Mo 412 deposition may be performed by ALD or CVD by flowing, for example, MoClₓ as Mo-containing precursor. The Mo 412 may nucleate selectively on the MoN layer 414 relative to oxide or nitride sidewall surfaces 408. The Mo 412 may continue to grow filling the volume in the feature 440 without forming a void. FIG. 4D shows the feature 460, which is an embodiment of the feature 440 after operation 250 is complete. After fill operation 250 in FIG. 2, Mo 412 fills the volume without any barrier or liner between the Mo 412 and the sidewall surfaces 408, maximizing the amount of conductive Mo. Also, void free Mo fill volume in the feature 460 from bottom up fill results in dense, high quality fill structure. When combined, all of these may lead to reduced Mo fill resistance. While FIG. 4C and FIG. 4D are described as separate operations, operations shown in FIG. 4C and FIG. 4D may belong to the same operation, and may be combined into the same operation. In some embodiments, FIG. 4C may represent an initial stage and FIG. 4D may represent a later stage of bottom-up fill.

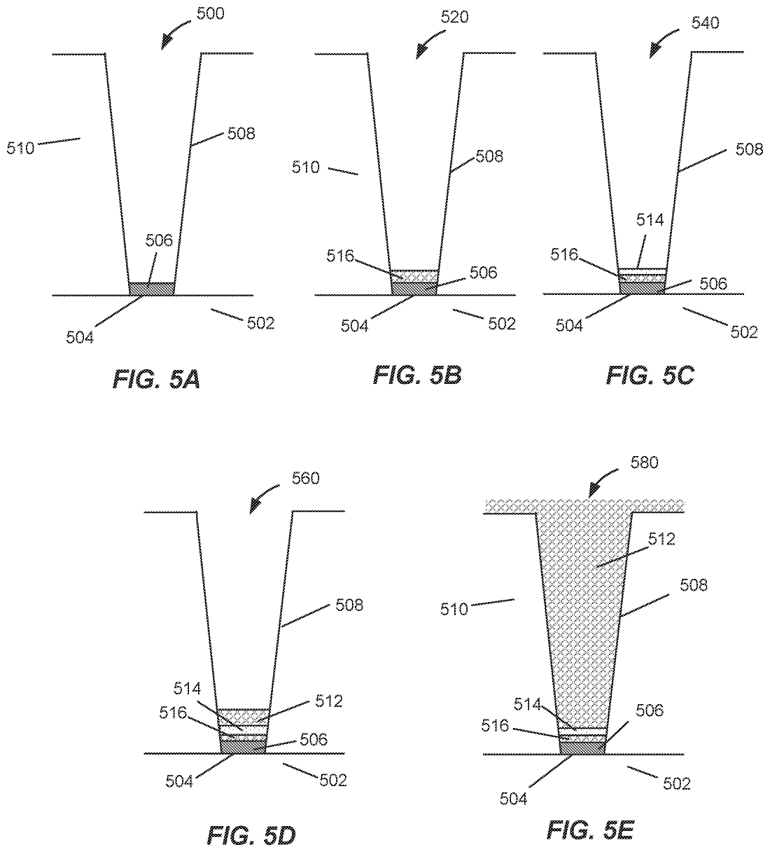

FIGS. 5A-5E show cross-sectional schematic illustrations of a feature of an example substrate after certain operations according to some embodiments. FIGS. 5A-5E show embodiments including operations 220, 230, 240, and 250 shown in FIG. 2.

FIG. 5A is an embodiment after operation 220 is performed at the bottom surfaces 504 in the feature 500. The bottom surfaces may be a Si or SiGe substrate 502, and may include n+ and/or p+ region. A MoSi layer 506 may be selectively formed on the Si or SiGe substrate 502. Process conditions for MoSi layer 506 deposition may be substantially identical to corresponding operation shown in FIG. 3A and/or FIG. 4A. Optionally, MoSi layer 506 may be exposed to one or more hydrogen-containing reactants, such as B₂H₆, SiH₄, Si₂H₆, or NH₃, thereby increasing the nuclei density of Mo in MoSi layer 506.

FIG. 5B is an embodiment for the feature 500 after a Mo layer 516 is deposited on the MoSi layer 506. A Mo layer 516 may be selectively formed when a Mo-containing precursor is selectively nucleated and grown on the MoSi layer 406 without substantially nucleating on the oxide or nitride sidewall surfaces 508. The thickness of Mo layer 516 may be about 0.3 to about 10 nm, or about 1 to about 10 nm, or about 3 to about 7 nm, or about 5 nm. In some embodiments, process conditions for Mo layer 516 deposition may be substantially the same as the Mo layer deposition shown in FIG. 5A. The Mo layer 516 may be formed by ALD or CVD by flowing MoClₓ as a Mo-containing precursor. Substrate temperature may range about 200 to about 600° C., or about 300 to about 500° C.

FIG. 5C shows an embodiment for the feature 520 after a MoN layer 514 is formed on the Mo layer 516. In some embodiments, a portion of the Mo layer 516 may be nitridized to form the MoN layer 514 by exposing to nitrogen radicals or nitrogen-containing radicals such as ammonia, nitrogen, ammonia plasma, nitrogen plasma, or a mixture thereof. An upper portion of the Mo layer 516 may be, with incorporation of nitrogen radicals or nitrogen-containing radicals, converted to MoN. A lower portion of the Mo layer 516 may still remain to be Mo. The thickness of Mo layer 516 converted may depend on nitridization parameters (e.g., time, flow rate, chamber pressure, chamber temperature etc.). Substrate temperature may range about 200 to about 600° C., or about 300 to about 500° C.

FIG. 5D shows an embodiment of the feature 540 while operation 250 is in progress. A Mo 512 may be selectively formed on the MoN layer 514 relative to the oxide or nitride sidewall surface 508 with a bottom-up fill. Once the Mo 512 is formed on the MoN layer 514, Mo may continue to fill the volume in the feature without changing deposition parameters. Mo 512 may continue to deposit on Mo 512 until Mo completely fill the volume in the feature 580 as shown in FIG. 5E. During Mo fill, Mo-containing precursor e.g., MoClₓ, may continue to selectively nucleate and grow on Mo already deposited, without nucleating on oxide or nitride sidewall surfaces 508. This bottom-up fill may produce a void free, dense fill structure. The deposition of Mo 512 in FIGS. 5D and 5E may be performed under the process conditions that are substantially similar to those used for Mo layer 516 deposition in FIG. 5A and/or FIG. 5B. While FIG. 5D and FIG. 5E are described as separate operations, operations shown in FIG. 5D and FIG. 5E may belong to the same operation, and may be combined into the same operation. In some embodiments, FIG. 5D may represent an initial stage and FIG. 5E may represent a later stage of bottom-up fill.

Selective Mo fill according to disclosed embodiments may be advantageous. Mo may be deposited under which it preferentially nucleates on the bottom surface in the features. This can promote bottom-up fill and prevent the formation of voids. Mo deposition in the feature does not require forming any barrier layers or other lining layers on the sidewalls in the feature. Accordingly, the entire volume in the feature may be filled by Mo, thereby reducing Mo fill resistance. Selective Mo fill may involve reduced number of operations by controlling deposition conditions, e.g., deposition temperature, deposition pressure, Mo-containing precursor or the like, which may result in increased throughput and reduced manufacturing cost.

### Apparatus

FIG. 6 schematically shows an embodiment of a process station 600 that may be used to deposit material using atomic layer deposition (ALD) and/or chemical vapor deposition (CVD), either of which may be thermal or plasma enhanced. The process station 600 may also be used in nitridization, silicidization, and/or fill of Mo in accordance with some embodiments as disclosed herein. For simplicity, the process station 600 is depicted as a standalone process station having a process chamber 602 for maintaining a low-pressure environment. However, it will be appreciated that a plurality of process stations 600 may be included in a common process tool environment. Further, it will be appreciated that, in some embodiments, one or more hardware parameters of process station 600, including those discussed in detail below, may be adjusted programmatically by one or more computer controllers.

The process station 600 fluidly communicates with reactant delivery system 601 for delivering process gases to a showerhead 606. Process gas may include one or more Mo-containing precursor, reactant, and/or carrier gas. For example, process gas may include Mo-containing precursor as disclosed herein, hydrogen (H₂), silane (SiH₄), disilane (Si₂H₆), diborane (B₂H₆), germane (GeH₄), ammonia (NH₃), hydrazine (N₂H₄), argon (Ar), or nitrogen (N₂). Reactant delivery system 601 includes a mixing vessel 604 for blending and/or conditioning process gases for delivery to showerhead 606. One or more mixing vessel inlet valves 620 may control introduction of process gases to mixing vessel 604. Similarly, a showerhead inlet valve 605 may control introduction of process gasses to the showerhead 606. In some embodiments, an inhibitor or other gas may be directly delivered to the process chamber 602. One or more mixing vessel inlet valves 620 may control introduction of process gases to mixing vessel 604. These valves may be controlled depending on whether a process gas, inhibition gas, or carrier gas may be turned on during various operations. In some embodiments, an inhibition gas may be generated by using an inhibition liquid and vaporizing using a heated vaporizer.

As an example, the embodiment of FIG. 6 includes a vaporization point 603 for vaporizing liquid reactant to be supplied to mixing vessel 604. In some embodiments, vaporization point 603 may be a heated vaporizer. The reactant vapor produced from such vaporizers may condense in downstream delivery piping. Exposure of incompatible gases to the condensed reactant may create small particles. These small particles may clog piping, impede valve operation, contaminate substrates, etc. Some approaches for addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 603 may be heat traced. In some examples, mixing vessel 604 may also be heat traced. In one non-limiting example, piping downstream of vaporization point 603 has an increasing temperature profile extending from approximately 100° C. to approximately 150° C. at mixing vessel 604.

In some embodiments, reactant liquid may be vaporized at a liquid injector. For example, a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 603. In one scenario, a liquid injector may be mounted directly to mixing vessel 604. In another scenario, a liquid injector may be mounted directly to showerhead 606.

In some embodiments, a liquid flow controller upstream of vaporization point 603 may be provided for controlling a mass flow of liquid for vaporization and delivery to process station 600. For example, the liquid flow controller (LFC) may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller.

Showerhead 606 distributes process gases toward substrate 612. In the embodiment shown in FIG. 6, substrate 612 is located beneath showerhead 606, and is shown resting on a pedestal 608. It will be appreciated that showerhead 606 may have any suitable shape, and may have any suitable number and arrangement of ports for distributing processes gases to substrate 612.

In some embodiments, a microvolume 607 is located beneath showerhead 606. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 608 may be raised or lowered to expose substrate 612 to microvolume 607 and/or to vary a volume of microvolume 607. For example, in a substrate transfer phase, pedestal 608 may be lowered to allow substrate 612 to be loaded onto pedestal 608. During a deposition process phase, pedestal 608 may be raised to position substrate 612 within microvolume 607. In some embodiments, microvolume 607 may completely enclose substrate 612 as well as a portion of pedestal 608 to create a region of high flow impedance during a deposition process.

Optionally, pedestal 608 may be lowered and/or raised during portions the deposition process to modulate process pressure, reactant concentration, etc., within microvolume 607. In one scenario where process chamber 602 remains at a base pressure during the deposition process, lowering pedestal 608 may allow microvolume 607 to be evacuated. Example ratios of microvolume to process chamber volume include, but are not limited to, volume ratios between 1:100 and 1:10. It will be appreciated that, in some embodiments, pedestal height may be adjusted programmatically by a suitable computer controller.

In another scenario, adjusting a height of pedestal 608 may allow a plasma density to be varied during plasma activation and/or treatment cycles included in the deposition process. At the conclusion of the deposition process phase, pedestal 608 may be lowered during another substrate transfer phase to allow removal of substrate 612 from pedestal 608.

While the example microvolume variations described herein refer to a height-adjustable pedestal, it will be appreciated that, in some embodiments, a position of showerhead 606 may be adjusted relative to pedestal 608 to vary a volume of microvolume 607. Further, it will be appreciated that a vertical position of pedestal 608 and/or showerhead 606 may be varied by any suitable mechanism within the scope of the present disclosure. In some embodiments, pedestal 608 may include a rotational axis for rotating an orientation of substrate 612. It will be appreciated that, in some embodiments, one or more of these example adjustments may be performed programmatically by one or more suitable computer controllers.

Returning to the embodiment shown in FIG. 6, showerhead 606 and pedestal 608 electrically communicate with RF power supply 614 and matching network 616 for powering a plasma. In some embodiments, the plasma energy may be controlled by controlling one or more of a process station pressure, a gas concentration, an RF source power, an RF source frequency, and a plasma power pulse timing. For example, RF power supply 614 and matching network 616 may be operated at any suitable power to form a plasma having a desired composition of radical species. Examples of suitable powers are included above. Likewise. RF power supply 614 may provide RF power of any suitable frequency. In some embodiments. RF power supply 614 may be configured to control high- and low-frequency RF power sources independently of one another. Example low-frequency RF frequencies may include, but are not limited to, frequencies between 50 kHz and 600 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some deposition processes, plasma strikes last on the order of a few seconds or more in duration. In certain implementations, much shorter plasma strikes may be used. These may be on the order of 10 ms to 1 second, typically, about 20 to 80 ms, with 50 ms being a specific example. Such very short RF plasma strikes require extremely quick stabilization of the plasma. To accomplish this, the plasma generator may be configured such that the impedance match is set preset to a particular voltage, while the frequency is allowed to float. Conventionally, high-frequency plasmas are generated at an RF frequency at about 13.56 MHz. In various embodiments disclosed herein, the frequency is allowed to float to a value that is different from this standard value. By permitting the frequency to float while fixing the impedance match to a predetermined voltage, the plasma can stabilize much more quickly, a result which may be important when using the very short plasma strikes associated with some types of deposition cycles.

In some embodiments, pedestal 608 may be temperature controlled via heater 610. In some implementations, the pedestal 608 may be heated to a temperature less than about 650° C., such as about between about 200° C. and about 600° C., or between about 300° C. and about 500° C., during deposition, nitridization, silicidization, and/or fill of Mo films as described in disclosed implementations. Further, in some embodiments, pressure control for process station 600 may be provided by butterfly valve 618. As shown in the embodiment of FIG. 6, butterfly valve 618 throttles a vacuum provided by a downstream vacuum pump (not shown). However, in some embodiments, pressure control of process station 600 may also be adjusted by varying a flow rate of one or more gases introduced to process station 600.

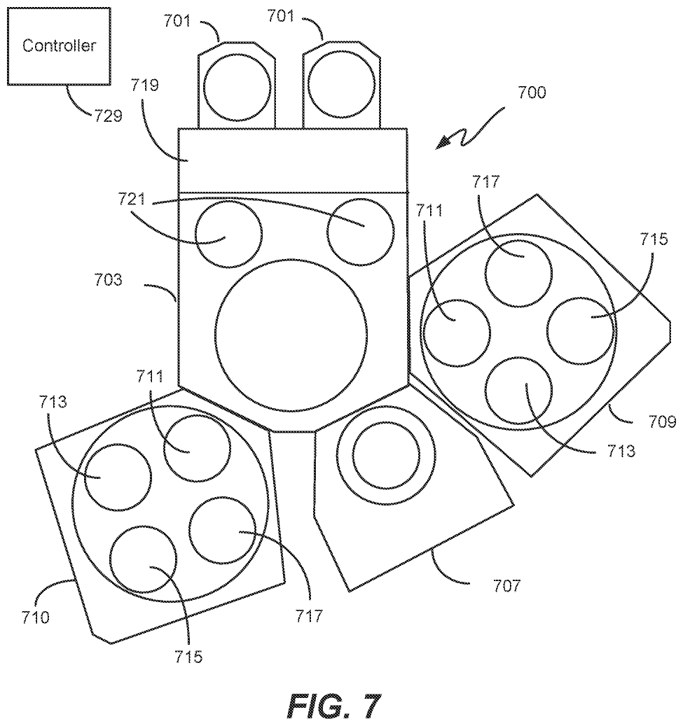

FIG. 7 is a block diagram of a processing system suitable for deposition, nitridization, silicidization, and/or fill of Mo in accordance with some embodiments. Mo may be deposited or filled using ALD and/or CVD, either of which may be thermal or plasma enhance. The system 700 includes a transfer module 703. The transfer module 703 provides a clean, pressurized environment to minimize risk of contamination of substrates being processed as they are moved between various reactor modules. Mounted on the transfer module 703 are two multi-station reactors 709 and 710, each capable of performing atomic layer deposition (ALD) and/or chemical vapor deposition (CVD) according to some embodiments. Reactors 709 and 710 may include multiple stations 711, 713, 715, and 717 that may sequentially or non-sequentially perform operations in accordance with disclosed embodiments. The stations may include a heated pedestal or substrate support, one or more gas inlets or showerhead or dispersion plate such that all operations, e.g., deposition, nitridization, silicidization, and/or fill, as disclosed herein may be performed in one reactor without breaking vacuum.

Also mounted on the transfer module 703 may be one or more single or multi-station modules 707 capable of performing plasma or chemical (non-plasma) pre-cleans, or any other processes described in relation to the disclosed methods. The module 707 may in some cases be used for various treatments to, for example, prepare a substrate for a deposition process. The module 707 may also be designed/configured to perform various other processes such as etching or polishing (e.g., chemical mechanical planarization). The system 700 also includes one or more wafer source modules 701, where wafers are stored before and after processing. An atmospheric robot (not shown) in the atmospheric transfer chamber 719 may first remove wafers from the source modules 701 to loadlocks 721. A wafer transfer device (generally a robot arm unit) in the transfer module 703 moves the wafers from loadlocks 721 to and among the modules mounted on the transfer module 703.

In various embodiments, a controller 729 is employed to control process conditions during deposition. The controller 729 will typically include one or more memory devices and one or more processors. A processor may include a CPU or computer, analog and/or digital input/output connections, stepper motor controller boards, etc.

The controller 729 may control all of the activities of the deposition apparatus. The controller 729 executes system control software, including sets of instructions for controlling the timing, mixture of gases, chamber pressure, chamber temperature, wafer (e.g., substrate) temperature, radio frequency (RF) power levels, wafer chuck or pedestal position, and other parameters of a particular process. Other computer programs stored on memory devices associated with the controller 729 may be employed in some embodiments.

Typically there will be a user interface associated with the controller 729. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe, and may be entered utilizing the user interface. Signals for monitoring the process may be provided by analog and/or digital input connections of the controller 729. The signals for controlling the process are output on the analog and digital output connections of the system 700.

The system software may be designed or configured in many different ways. For example, various chamber component subroutines or control objects may be written to control operation of the chamber components necessary to carry out the deposition processes (and other processes, in some cases) in accordance with the disclosed embodiments. Examples of programs or sections of programs for this purpose include substrate positioning code, process gas control code, pressure control code, and heater control code.

In some implementations, the controller 729 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 729, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

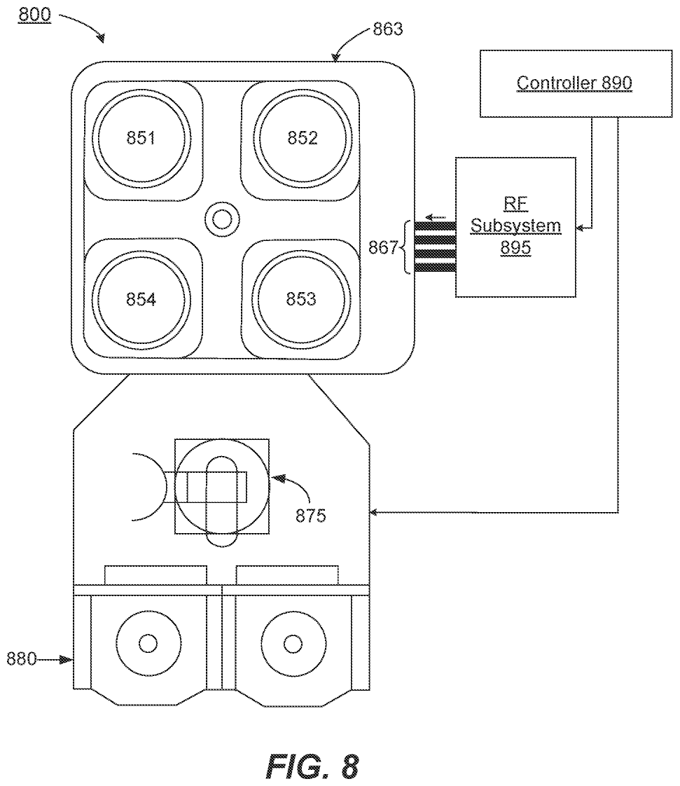

It may be appreciated that a plurality of process stations may be included in a multi-station processing tool environment, such as shown in FIG. 8, which depicts a schematic view of an embodiment of a multi-station processing tool. Processing apparatus 800 employs an integrated circuit fabrication chamber 863 that includes multiple fabrication process stations, each of which may be used to perform processing operations on a substrate held in a wafer holder, such as a pedestal, at a particular process station. In the embodiment of FIG. 8, the integrated circuit fabrication chamber 863 is shown having four process stations 851, 852, 853, and 854. Other similar multi-station processing apparatuses may have more or fewer process stations depending on the implementation and, for example, a desired level of parallel wafer processing, size/space constraints, cost constraints, etc. Also shown in FIG. 8 is substrate handler robot 875, which may operate under the control of system controller 890, configured to move substrates from a wafer cassette (not shown in FIG. 8) from loading port 880 and into integrated circuit fabrication chamber 863, and onto one of process stations 851, 852, 853, and 854.

FIG. 8 also depicts an embodiment of a system controller 890 employed to control process conditions and hardware states of processing apparatus 800. System controller 890 may include one or more memory devices, one or more mass storage devices, and one or more processors, as described herein.

RF subsystem 895 may generate and convey RF power to integrated circuit fabrication chamber 863 via radio frequency input ports 867. In particular embodiments, integrated circuit fabrication chamber 863 may comprise input ports in addition to radio frequency input ports 867 (additional input ports not shown in FIG. 8). Accordingly, integrated circuit fabrication chamber 863 may utilize 8 RF input ports. In particular embodiments, process stations 851-854 of integrated circuit fabrication chamber 863 may each utilize first and second input ports in which a first input port may convey a signal having a first frequency and in which a second input port may convey a signal having a second frequency. Use of dual frequencies may bring about enhanced plasma characteristics.

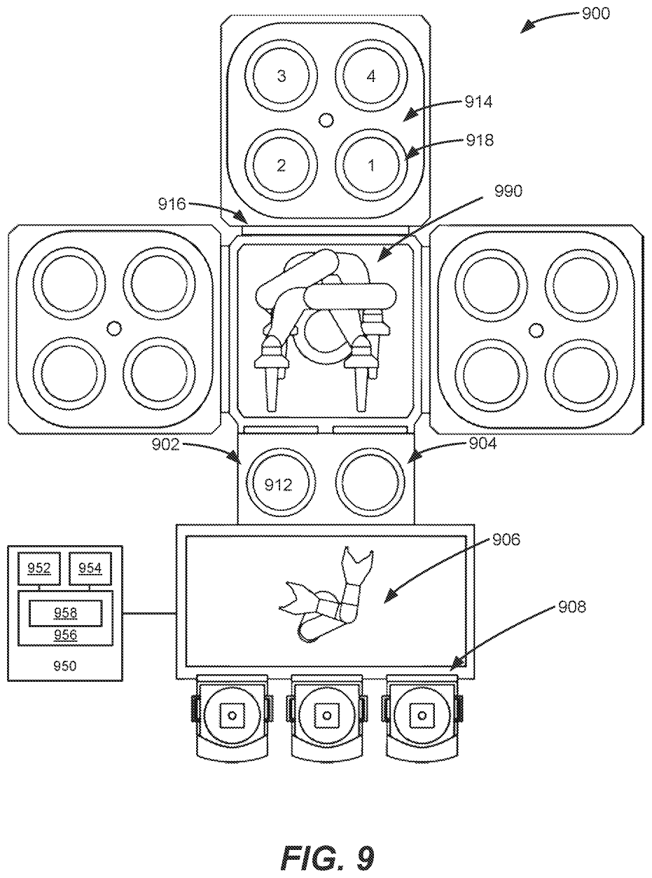

As described above, one or more process stations may be included in a multi-station processing tool. FIG. 9 shows a schematic view of an embodiment of a multi-station processing tool 900 with an inbound load lock 902 and an outbound load lock 904, either or both of which may comprise a remote plasma source. A robot 906, at atmospheric pressure, is configured to move substrates or wafers from a cassette loaded through a pod 908 into inbound load lock 902 via an atmospheric port 910. A substrate is placed by the robot 906 on a pedestal 912 in the inbound load lock 902, the atmospheric port 910 is closed, and the load lock is pumped down. Where the inbound load lock 902 comprises a remote plasma source, the substrate may be exposed to a remote plasma treatment in the load lock prior to being introduced into a processing chamber 914. Further, the substrate also may be heated in the inbound load lock 902 as well, for example, to remove moisture and adsorbed gases. Next, a chamber transport port 916 to processing chamber 914 is opened, and another robot (not shown) places the substrate into the reactor on a pedestal of a first station shown in the reactor for processing. While the embodiment depicted in FIG. 9 includes load locks, it will be appreciated that, in some embodiments, direct entry of a substrate into a process station may be provided. In various embodiments, the soak gas is introduced to the station when the substrate is placed by the robot 906 on the pedestal 912.

The depicted processing chamber 914 comprises four process stations, numbered from 1 to 4 in the embodiment shown in FIG. 9. Each station has a heated pedestal (shown at 918 for station 1), and gas line inlets. It will be appreciated that in some embodiments, each process station may have different or multiple purposes. For example, in some embodiments, a process station may be switchable between an ALD and PEALD process mode. Additionally or alternatively, in some embodiments, processing chamber 914 may include one or more matched pairs of ALD and PEALD process stations. While the depicted processing chamber 914 includes four stations, it will be understood that a processing chamber according to the present disclosure may have any suitable number of stations. For example, in some embodiments, a processing chamber may have five or more stations, while in other embodiments a processing chamber may have three or fewer stations.

FIG. 9 depicts an embodiment of a wafer handling system 990 for transferring substrates within processing chamber 914. In some embodiments, wafer handling system 990 may transfer substrates between various process stations and/or between a process station and a load lock. It will be appreciated that any suitable wafer handling system may be employed. Non-limiting examples include wafer carousels and wafer handling robots. FIG. 9 also depicts an embodiment of a system controller 950 employed to control process conditions and hardware states of process tool 900. System controller 950 may include one or more memory devices 956, one or more mass storage devices 954, and one or more processors 952. Processor 952 may include a CPU or computer, analog and/or digital input/output connections, stepper motor controller boards, etc. In some embodiments, system controller 950 includes machine-readable instructions for performing operations such as those described herein.

In some embodiments, system controller 950 controls the activities of process tool 900. System controller 950 executes system control software 958 stored in mass storage device 954, loaded into memory device 956, and executed on processor 952. Alternatively, the control logic may be hard coded in the system controller 950. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 958 may include instructions for controlling the timing, mixture of gases, amount of gas flow, chamber and/or station pressure, chamber and/or station temperature, substrate temperature, target power levels, RF power levels, substrate pedestal, chuck and/or susceptor position, and other parameters of a particular process performed by process tool 900. System control software 958 may be configured in any suitable way. For example, various process tool component subroutines or control objects may be written to control operation of the process tool components used to carry out various process tool processes. System control software 958 may be coded in any suitable computer readable programming language.

### Conclusion

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method comprising:
forming a molybdenum silicide layer on a bottom surface of a recessed feature on a substrate, the bottom surface comprising silicon or silicon germanium; and
depositing a first molybdenum layer on or over the molybdenum silicide layer to fill the recessed feature.

2. The method of claim 1, further comprising:
exposing the molybdenum silicide layer to a reducing agent comprising diborane, silane, disilane, or a mixture thereof prior to depositing the first molybdenum layer.

3. The method of claim 1, further comprising:
prior to depositing the first molybdenum layer, forming a second molybdenum layer on the molybdenum silicide laver; and
exposing the second molybdenum layer to nitrogen radicals or nitrogen-containing radicals.

4. The method of claim 3, wherein a portion of the second molybdenum layer is converted to a molybdenum nitride layer when exposed to the nitrogen radicals or nitrogen-containing radicals.

5. The method of claim 1, further comprising:
exposing the molybdenum silicide layer to nitrogen radicals or nitrogen-containing radicals,
wherein the nitrogen radicals or nitrogen-containing radicals comprise ammonia, nitrogen, ammonia plasma, nitrogen plasma, or a mixture thereof.

6. The method of claim 5, further comprising:
exposing the molybdenum silicide layer to a reducing agent comprising diborane, silane, disilane, or a mixture thereof prior to exposing the molybdenum silicide layer to nitrogen radicals or nitrogen-containing radicals.

7. The method of claim 1, wherein the molybdenum silicide layer is formed by reacting a molybdenum containing precursor with the bottom surface at a temperature of about 200 to about 600° C.

8. The method of claim 1, wherein the first molybdenum layer is formed by flowing a molybdenum halide precursor or a molybdenum oxyhalide precursor.

9. The method of claim 1, wherein the molybdenum silicide layer has a thickness of about 0.3 to about 10 nm.

10. The method of claim 1, wherein the molybdenum silicide layer has a thickness of about 2 to about 20 nm.
